(19) United States
(12) Patent Application Publication
(10) Pub. No.: US 2026/0293683 A1
(43) Pub. Date: Sep. 24, 2026

(54) APPARATUSES AND METHODS TO CONTROL WAFER WARPAGE COMPENSATION ALONG X/Y DIRECTIONS

(71) Applicant: Lam Research Corporation, Fremont, CA (US)

(72) Inventors: Yanhui Huang, Sherwood, OR (US); Ruisong Wang, Tigard, OR (US); Fayaz A. Shaikh, Lake Oswego, OR (US); MIchael Anthony Chan, Beaverton, OR (US)

(21) Appl. No.: 19/484,321

(22) PCT Filed: May 30, 2024
(86) PCT No.: PCT/US2024/031778

§ 371 Date: Nov. 13, 2025

Related U.S. Application Data
(60) Provisional application No. 63/505,354, filed on May 31, 2023.
(60) Provisional application No. 63/516,068, filed on Jul. 27, 2023.

(51) Int. Cl. H10W 42/00

(52) U.S. Cl. CPC H10W 42/121

(57) ABSTRACT

Provided are methods, apparatuses, and structure for mitigating wafer bow of a semiconductor wafer. Deposition of a backside layer stack may mitigate wafer bow that varies in orthogonal directions. Each of the backside layers may be deposited by a backside deposition apparatus. Therefore, they provide a complementary film stack having a substantially flat surface on the backside of the substrate.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

In semiconductor processing, it may be desired that a wafer remains substantially flat. However, during normal operations, a wafer may experience wafer bow. The wafer bow may cause issues such as improper clamping by an electrostatic chuck, inability to be held by a wafer handler, process conditions nonuniformity, misalignment and/or pattern transfer issues during photolithography, and others, which would degrade or damage the performance of the devices and decrease yields and productivity. Apparatuses and processes have been developed to manage wafer bow by keeping the wafer flat within process tolerances. One process includes depositing a film on the backside of the wafer to counteract any stress that may be causing the wafer to bow.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor implicitly admitted as prior art against the present disclosure.

### SUMMARY

Disclosed herein are methods and systems of depositing films. In one aspect of the embodiments herein, a method of reducing bow in a substrate is provided, the method including: receiving a substrate having a frontside and a backside, wherein the substrate has a first bow in an x-direction of the substrate and a second bow in a y-direction of the substrate; performing one or more cycles of: (a) forming a first backside layer on the backside of the substrate, wherein the first backside layer compensates the first bow more than it compensates the second bow or compensates the second bow more than it compensates the first bow, and wherein the first backside layer has a first type of internal stress and a first non-uniform thickness profile; and (b) forming a second backside layer on the backside of the substrate, wherein the second backside layer compensates either of the first bow or the second bow that was less compensated by the first backside layer, wherein the second backside layer has a second type of internal stress, which is opposite the first type of internal stress, and a second non-uniform thickness profile; and wherein the first non-uniform thickness profile and the second non-uniform thickness profile complement each other, such that when the first backside layer and second backside layers are formed, they provide a complementary film stack having a substantially flat surface on the backside of the substrate.

In some embodiments, the substrate is a semiconductor wafer having partially fabricated integrated circuits on the front side. In some embodiments, the substrate has a saddle-shaped bow. In some embodiments, the method further includes prior to forming the first backside layer, determining that the first bow is greater in magnitude than the second bow. In some embodiments, the method further includes prior to forming the first backside layer, rotating the substrate based on the determination that the first bow is greater in magnitude than the second bow. In some embodiments, the first non-uniform thickness profile is a curved bar that is thicker toward a center of the substrate than edges of the substrate. In some embodiments, the curved bar has a longitudinal axis that is substantially parallel to the y-direction. In some embodiments, the curved bar has a generally parabolic shape that varies in thickness in a z-direction perpendicular to the x-and y-directions, away from the backside of the substrate as a function of the x-direction. In some embodiments, the second non-uniform thickness profile is a curved channel that is thicker toward edges of the substrate than a center of the substrate. In some embodiments, the curved channel has a parabolic shape that varies in thickness in a z-direction, away from the backside of the substrate as a function of the x-direction. In some embodiments, the first type of internal stress is a tensile stress. In some embodiments, the first type of internal stress is a compressive stress. In some embodiments, further including forming a third backside layer on the backside of the substrate, wherein the third backside layer has a uniform shape and either the first or the second type of internal stress. In some embodiments, the type of internal stress and a magnitude of the internal stress of the third backside layer is based upon the bow of the substrate after forming the first backside layer and the second backside layer. In some embodiments, further including identifying a value of the first bow and a value of the second bow, and wherein forming the first backside layer and forming the second backside layer are based upon the value of the first bow and the value of the second bow. In some embodiments, further including identifying a value of the first bow and a value of the second bow, and wherein a magnitude of the internal stress of the first backside layer and a magnitude of the internal stress of the second backside layer are based upon the value of the first bow and the value of the second bow. In some embodiments, the one or more cycles are two or more cycles. In some embodiments, a total thickness of layers deposited during the one or more cycles is at least about 2 μm. In some embodiments, the first backside layer and the second backside layer together have a first thickness, and each cycle of (a) and (b) deposit complementary profile layers having the first thickness. In some embodiments, the first thickness is less than about 1 μm. In some embodiments, first backside layer and the second backside layer exhibit a change in wafer bow compensation after annealing less than about 20%. In some embodiments, the method further includes after performing the one or more cycles, forming a third backside layer on the backside of the substrate, wherein the third backside layer increases a flatness of the backside of the substrate. In some embodiments, further including performing a plasma treatment after forming the first backside layer, performing a plasma treatment after forming the second backside layer, or both, wherein the plasma treatment improves adhesion of backside layers.

In another aspect of the embodiments herein, a substrate is provided, the substrate including: one or more frontside layers on a frontside of the substrate, wherein the substrate has a first bow in an x-direction of the substrate and a second bow in a y-direction of the substrate; a first backside layer on a backside of the substrate, wherein the first backside layer compensates the first bow more than it compensates the second bow or compensates the second bow more than it compensates the first bow, and wherein the first backside layer has a first type of internal stress and a first non-uniform thickness profile; a second backside layer on the backside of the substrate, wherein the second backside layer compensates either of the first bow or the second bow that was less compensated by the first backside layer, wherein the second backside layer has a second type of internal stress, which is opposite the first type of internal stress, and a second non-uniform thickness profile; and wherein the first non-uniform thickness profile and the second non-uniform thickness profile complement each other, such that when the first backside layer and second backside layers are formed, they provide a complementary film stack having a substantially flat surface on the backside of the substrate.

In some embodiments, if from the one or more frontside layers are not compensated by the first backside layer, the substrate has a first bow or a second bow of about 300 μm or more. In some embodiments, the first non-uniform thickness profile is a curved bar that is thicker toward a center of the substrate than edges of the substrate. In some embodiments, the curved bar has a longitudinal axis that is substantially parallel to the y-direction. In some embodiments, the curved bar has a generally parabolic shape that varies in thickness in a z-direction perpendicular to the x-and y-directions, away from the backside of the substrate as a function of the x-direction. In some embodiments, the second non-uniform thickness profile is a curved channel that is thicker toward edges of the substrate than a center of the substrate. In some embodiments, the curved channel has a parabolic shape that varies in thickness in a z-direction, away from the backside of the substrate as a function of the x-direction. In some embodiments, the first type of internal stress is a tensile stress. In some embodiments, the first type of internal stress is a compressive stress. In some embodiments, further including a third backside layer on the backside of the substrate, wherein the third backside layer has a uniform shape and either the first or the second type of internal stress. In some embodiments, the type of internal stress and a magnitude of the internal stress of the third backside layer is based upon bowing of the substrate after forming the first backside layer and the second backside layer. In some embodiments, further including additional complementary film stacks. In some embodiments, the complementary film stack and the additional complementary film stacks together alternate between the first backside layer and the second backside layer. In some embodiments, a total thickness of all complementary film stacks is at least about 2 μm. In some embodiments, a thickness of each complementary film stack is less than about 1 μm. In some embodiments, a change in total wafer bow compensation of all of the complementary film stacks after annealing is less than about 20%. In some embodiments, further including a third backside layer on the backside of the substrate deposited after all of the complementary film stacks, wherein the third backside layer increases a flatness of the backside of the substrate.

In another aspect of the embodiments herein, an apparatus is provided, the apparatus including: a process chamber; and a controller including memory and processors configured for: receiving a substrate having a frontside and a backside, wherein the substrate has a first bow in an x-direction of the substrate and a second bow in a y-direction of the substrate; performing one or more cycles of: (a) forming a first backside layer on the backside of the substrate, wherein the first backside layer compensates the first bow more than it compensates the second bow or compensates the second bow more than it compensates the first bow, and wherein the first backside layer has a first type of internal stress and a first non-uniform thickness profile; and (b) forming a second backside layer on the backside of the substrate, wherein the second backside layer compensates either of the first bow or the second bow that was less compensated by the first backside layer, wherein the second backside layer has a second type of internal stress, which is opposite the first type of internal stress, and a second non-uniform thickness profile; and wherein the first non-uniform thickness profile and the second non-uniform thickness profile complement each other, such that when the first backside layer and second backside layers are formed, they provide a complementary film stack having a substantially flat surface on the backside of the substrate.

These and other features of the disclosed embodiments will be described in detail below with reference to the associated drawings.

### BRIEF DESCRIPTION OF DRAWINGS

FIGS. 1A and 1B show examples of unbowed and bowed semiconductor wafers on an electrostatic chuck.

FIG. 2 shows example isometric views of various wafer bow shapes.

FIG. 3A illustrates exemplary zones for depositing films having a curved bar profile and a curved channel profile on a backside of a wafer according to various embodiments herein.

FIGS. 3B and 3C illustrate a side view and exploded side view of a wafer having backside layers having a curved bar profile and a curved channel profile according to various embodiments herein.

FIGS. 3D-3G illustrate side views of a wafer having alternating stack of backside layers having a curved bar profile and a curved channel profile according to various embodiments herein.

FIG. 4A-B are graphs showing internal stress of individual tensile and compressive films and a stacked film according to various embodiments herein.

FIG. 4C is an isometric view of a bowed wafer according to various embodiments herein.

FIG. 5 is a process flow diagram illustrating certain operation in semiconductor wafer processing.

FIGS. 6A and 6B show a block diagram of an example substrate processing system.

FIG. 7A shows an example cross section of an edge of a shower-pedestal.

FIG. 7B shows a top view of an example carrier ring.

FIG. 8 shows a schematic of an example process system that may be used to perform the methods described herein.

### DETAILED DESCRIPTION

### Terminology

The following terms are used throughout the instant specification:

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, 300 mm, or 450 mm. Examples of wafer materials include silicon (Si), gallium arsenide (GaAs), and silicon germanium (SiGe). Besides semiconductor wafers, other workpieces that may take advantage of the disclosed embodiments include various articles such as printed circuit boards, magnetic recording media, magnetic recording sensors, mirrors, optical elements, display devices or components such as backplanes for pixelated display devices, flat panel displays, micro-mechanical devices and the like. The workpiece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

“Wafer bow” as used herein may refer to a deformation of a wafer. The deformation may have radial and/or azimuthal components. Examples of types of wafer bow include dome shapes, bowl shapes, and saddle shapes. Wafer bow may occur during fabrication, for example, as a result of stress to the wafer during deposition of materials on an active surface of a wafer. Wafer bow may occur during various types of fabrication, such as when large stacks of materials are deposited. Wafer bow may cause complications in subsequent processing steps. For example, the wafer may fail to chuck correctly if an amount of bowing is too large, which may subject the wafer to nonuniform heating and/or other process conditions. Moreover, some processing steps (e.g., photolithography) may produce poor results if performed on a wafer that is excessively bowed.

In some embodiments, wafer bow may be measured as a deviation of the mean or median distance of the surface of the wafer to a reference plane. In some embodiments, the point of the median surface of the wafer may be the center point (e.g., in the case of concave or domed bowing), or an edge point of the wafer and/or an average edge point of the wafer (e.g., in the case of warping or convex bowing). In some embodiments wafer bow may be measured from a reference plane such that when an edge point of the wafer is below the reference plane the edge point is considered to have a negative bow, and when the edge point of the wafer is above the reference plane the edge point is considered to have a positive bow. In some embodiments, positive or negative bow may be measured along a z axis perpendicular to the reference plane.

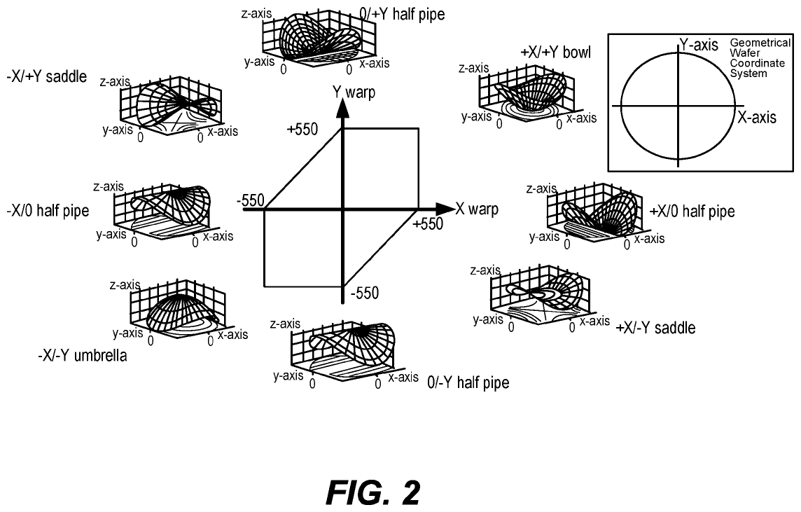

In some embodiments, wafer bow may vary between the two principal planar directions of a substrate, which are referred to as the x and y directions. For example, wafer bow along the x direction may be in a positive z direction while wafer bow along the y direction may be in a negative z direction (the z axis being perpendicular to a plane formed by the planar x and y directions). FIG. 2 illustrates 8 shapes that may be formed based on bowing in x and y directions. When bowing is positive along the x and y directions, a bowl shape is formed, while when bowing is negative in the x and y directions, an umbrella or dome shape is formed. Other shapes include a “half pipe” or “taco” shape when there is substantially no wafer bow in one direction while a positive or negative bow in the planar perpendicular direction. When wafer bow is positive in one direction and negative in another direction, a “saddle” or “potato chip” shape is formed.

Wafer bowing may be characterized by x-bow and y-bow values. A positive x-bow value corresponds to bowing of the wafer in a positive z-direction at a coordinate of the wafer having a large x-value and a small or zero y-value, e.g., an x-value greater than about 100 mm or of about 150 mm (for a 300 mm wafer) and a y-value of about 0 mm (where the reference point is at a center of the wafer). A negative x-bow value similarly corresponds to bowing of the wafer in a negative z-direction at a coordinate of the wafer having a large x-value and a small or zero y-value. Conversely, a positive y-bow and negative y-bow correspond to bowing of the wafer in positive or negative z-directions, respectively, at a coordinate of the wafer having a large y-value and a small or zero x-value.

In some embodiments, wafer bow may be characterized by a single value. In some embodiments, wafer bow may be described as a “delta bow.” When referring to wafer bow of saddle-shaped wafers, the wafer delta bow may be expressed in terms of a difference between the negative-bow in one direction (such as along the x-axis) and positive-bow in another direction (such as along the y-axis). For example, a wafer bow of 200 μm may result from an x-bow of −25 um and a y-bow of +175 μm. For wafers having a taco, bowl, or dome-shaped wafer bow, wafer bow may refer to a difference between the maximum bow and a reference plane as described above.

A “curved bar profile” is characterized by a two-dimensional shape that has a varying thickness along one of the two principal planar dimensions of a substrate, which are referred to as the x and y directions. While the thickness varies in one of these two directions, it does not substantially vary in the other direction. Further, the curved bar profile means that the thickness of the layer is generally thicker toward the center of the substrate than the edges of the substrate. Hence the structure appears like a bar or “speed bump” on the backside of the substrate. In some cases, the curved bar profile varies in the direction away from the plane of the substrate (the z-direction) as a function of x-axis position, but without significantly varying in the y-axis position. In other cases, the curved bar profile varies in the z direction as a function of y-axis position, but without significantly varying in the x-axis position. In certain embodiments, a curved bar is disposed along a principal axis of the substrate such that a centerline of the bar passes through the origin (center point) of the substrate. Thus, the curved bar profile may be characterized by a film having greater thickness in the center of the substrate than the edge of the substrate. The curved shape may be generally rounded such a circular, parabolic, gaussian, etc.

A “curved channel profile” is characterized by a two-dimensional shape that has a varying thickness along one of the x and y directions of the substrate, which are referred to as the x and y directions. While the thickness varies in one of these two directions, it does not substantially vary in the other direction. Further, the curved bar profile means that the thickness of the layer is generally thicker toward the edges of the substrate than the center of the substrate. Hence the structure appears like a channel or indentation on the backside of the substrate. In some cases, the curved channel profile varies in the direction away from the plane of the substrate (the z-direction) as a function of x-axis position, but without significantly varying in the y-axis position. In other cases, the curved channel profile varies in the z direction as a function of y-axis position, but without significantly varying in the x-axis position. In certain embodiments, a curved channel is disposed along a principal axis of the substrate such that a centerline of the channel passes through the origin (center point) of the substrate. Thus, the curved channel profile may be characterized by a film having greater thickness at the edges of the substrate than the center of the substrate. The curved shape may be generally rounded such as a circular, parabolic, gaussian, etc.

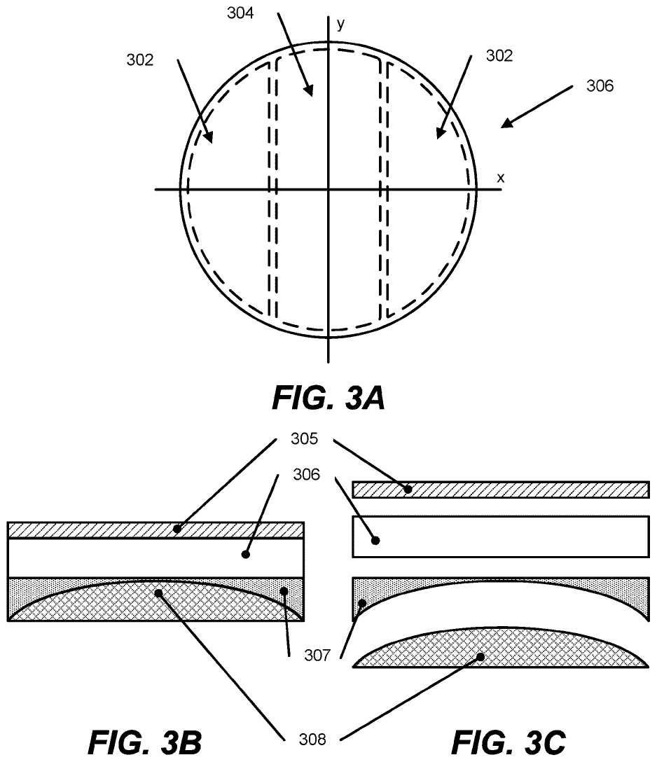

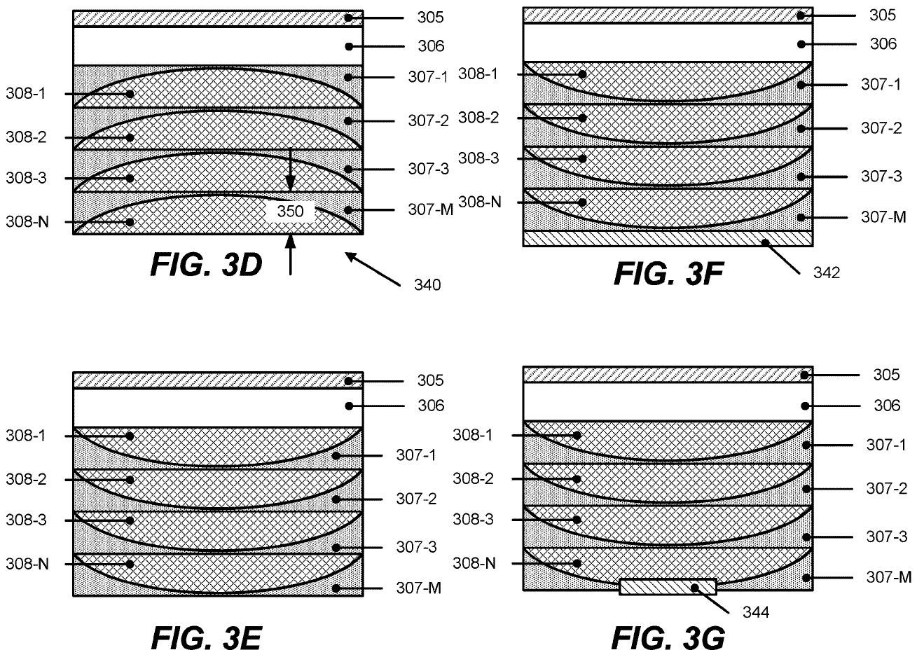

Generally, the curved bar and curved channel profiles refer to geometries of the films' varying properties. Frequently, the film property is film thickness, but other properties can similarly assume the profiles. Such properties may include film density, film composition, film internal stress, etc. Examples of a curved bar profile and a curved channel profile are illustrated in FIGS. 3B and 3C. Film 308 is an example of a curved bar profile, while film 307 is an example of a curved channel profile. A curved bar profile film and a curved channel profile film may also be referred to as non-uniform thickness profile films. A non-uniform thickness profile film may refer to either of a curved bar profile film or a curved channel profile film.

A “uniform thickness profile” is characterized by a two-dimension shape that has a substantially non-varying thickness along any planar directions of a substrate, e.g., an x and y direction. In some embodiments, the combination of a curved channel profile film and a curved bar profile film may be a uniform thickness film. In some embodiments, a curved channel profile film and a curved bar profile film have complementary shapes that together may form a substantially uniform thickness profile bilayer film. In some embodiments, the combination of a curved bar profile film and a curved channel profile film may be referred to as a stack of complementary profile films. In some embodiments, a non-uniform thickness profile may refer to either or both of a curved channel profile and a curved bar profile. In some embodiments, a stacked film formed from combination of layers having a curved channel profile and layers of having a curved bar profile may be substantially flat, e.g., having a flatness similar to a single uniform thickness profile film deposited to a similar thickness as the combined non-uniform thickness profile films.

### Bowed Wafers

Semiconductor device fabrication often involves deposition of a stack of layers or films on a wafer. Typically, most deposition and other processing to form the devices occurs on one side of the wafer, often referred to as the front face or frontside of a wafer. As the deposited layers build up, they can introduce stress in the wafer. A large net tensile or compressive stress can cause the wafer to bow (and potentially crack in case of excessive tensile stress), which is undesirable.

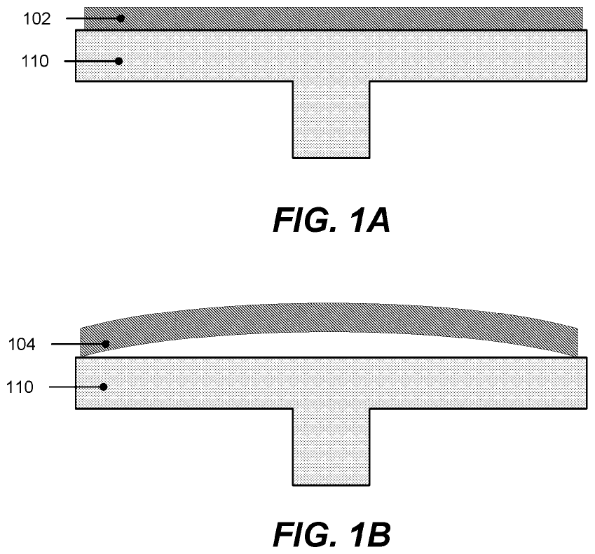

Bowing is especially likely to occur where large stacks of materials are deposited, for example, in the context of 3D-NAND devices, or where a thick frontside layer is deposited. Where bowing is significant, it can deleteriously affect subsequent processing steps. For instance, the wafer may fail to chuck correctly if the bowing is too great. FIGS. 1A and 1B show a wafer on an electrostatic chuck, which typically have a flat surface. FIG. 1A shows a wafer 102 on an electrostatic chuck 110. When the wafer 102 is substantially flat for purposes of a particular process operation, e.g., having a bow of about 100 μm or less, the wafer may be properly clamped, securing the wafer for subsequent processing steps. FIG. 1B shows a bowed wafer 104 on the electrostatic chuck 110. Wafer 104 is illustrated as having a negative wafer bow (i.e., a dome shape where the center point of the wafer is above the edge of the wafer). This may result from frontside layers having a compressive internal stress. Frontside layers having a tensile internal stress may cause a wafer to bow in the opposite manner, having a bowl shape.

When the bow is significant, various manufacturing problems may arise. In some instances, the wafer may fail to secure properly on the electrostatic chuck. This may cause various nonuniformity issues—for example, the wafer may not be heated uniformly, the process gases may not be applied to the wafer uniformly across the wafer, and/or the distance between the wafer and the showerhead and/or showerhead pedestal may not be maintained evenly in parallel (i.e., parallelism may be disrupted). Wafer bow may cause other problems. For example, certain processing steps (e.g., photolithography) are very precise and produce poor results if the wafer is not substantially flat. The problem may be manifest as lithography defocus. Cracking may also occur, which can introduce additional defects, reducing yield.

One example stack that may cause these problems is a stack having alternating layers of oxide and nitride (e.g., silicon oxide/silicon nitride/silicon oxide/silicon nitride, etc.). Another example of a type of stack likely to cause bowing includes alternating layers of oxide and polysilicon (e.g., silicon oxide/polysilicon/silicon oxide/polysilicon, etc.). Other examples of stack materials that may be problematic include, but are not limited to, tungsten and titanium nitride.

The materials in the stacks may be deposited through chemical vapor deposition (CVD) techniques such as plasma enhanced chemical vapor deposition (PECVD), low pressure chemical vapor deposition (LPCVD), metal organic chemical vapor deposition (MOCVD), atomic layer deposition (ALD), or plasma enhanced atomic layer deposition (PEALD), or through direct metal deposition (DMD), etc. These examples are not intended to be limiting. Certain disclosed embodiments may be useful whenever wafer stress and/or bowing are induced due to material present on the frontside of the wafer.

The frontside stacks may be deposited to any number of layers and thicknesses. In an example, the stack may include about 20 or more layers, and have a total thickness of about 2 μm to about 4 μm. In some cases, multiple-layer stacks may include about one hundred or more layers. In some embodiments, multiple-layer stacks may have about five hundred or more layers. In some embodiments, the multiple-layer stacks may have about one thousand or more layers. Such stacks may have a thickness of about 4 μm to 12 μm, for example.

The stress induced in the wafer by the stack or other frontside deposition may be about −500 MPa to about +500 MPa. In some embodiments, the resulting in a bow is about 150 μm or greater, e.g., about 300 μm and above, about 400 μm and above, or about 200 μm to about 400 μm (for a 300 mm wafer).

Another cause of wafer bow may be frontside processing which uses thick hardmasks with limited etch selectivity. In these embodiments, at least one of the one or more frontside layers is a hardmask. The thick hardmasks may have an internal stress similar to those described above, e.g., have a magnitude of 0 MPa to about 500 MPa. The stress caused by the hardmask may be tensile stress or compressive stress. The thick hardmasks may cause wafers to have a significant wafer bow, e.g., about 150 μm or more.

Various techniques have been devised for combatting bowing. When bowing is severe, deposition processes may be tuned to reduce or counteract internal stresses in deposited layers. However, any such tuning should not interfere with process requirements for fabricating devices. One commonly used technique to counteract bowing deposits layers on the backside of the wafer.

Backside deposition may form a high-stress film on the backside of the wafer intentionally to control overall stress and bowing of the wafer. If the backside layer has the same type of internal stress (tensile or compressive) and of comparable magnitude to the internal stress created on the frontside of the wafer, the backside film effectively counteracts and reduces the bow of the wafer.

Examples of backside films used to counteract bow include the following: amorphous silicon, silicon oxide, silicon nitride, and silicon oxynitride. Variations of these films may be used, such as doped amorphous silicon, doped silicon oxide, doped silicon nitride, and doped silicon oxynitride; and these films may be formed under different deposition conditions to tune and optimize their material properties. Also, other types of films that may be introduced during the semiconductor process may be used in conjunction with, and/or instead of, these exemplary films. Current backside films have high internal stress and can mitigate the stresses imparted on the wafer from the frontside layers to reduce or eliminate the wafer bow. Although not required, generally, backside layers are made of films with high stress when deposited on the silicon wafer. High-stress films may be preferred because a high-stress films may compensate the wafer bow more efficiently.

In some embodiments, backside film thicknesses are relatively uniform because the bow caused by depositing material on the frontside is relatively symmetrical, forming a bowl or dome shape based on an isotropic internal stress. Thus, depositing a uniform thickness profile film, either with tensile or compressive internal stress, could mitigate the stress imparted on a wafer from the frontside layers as the backside film would impart an opposite wafer bow that is similarly symmetrical. However, certain frontside deposition techniques may cause anisotropic stress, such that the internal stress on the frontside of the wafer, and hence the resultant bowing, varies in one principal planar direction compared to another principal planar direction, e.g., x and y directions. In such embodiments a wafer may have x-bow and y-bow that are different in magnitude as well as direction (or sign). A uniform backside layer may insufficiently address such saddle-shaped wafer bow.

FIG. 2 illustrates 8 different shapes that may form based on different combinations of positive or negative bowing along x and y axes or directions. A bowl, umbrella, half pipe, or saddle shape may be formed depending on whether wafer bow along the x and y directions is positive, negative, or substantially non-existent. When a wafer bow shape is a bowl or umbrella, a uniform thickness profile film having an isotropic tensile or compressive internal stress may properly mitigate the stress imparted on the wafer from frontside layers. However, when the wafer bow shape is a different shape, e.g., a saddle or half pipe shape, an isotropic internal stress would either over or under compensate wafer bow along the x or y direction, or potentially exaggerate wafer bow. For example, an isotropic tensile backside film deposited on a wafer having a negative x-bow and positive y-bow (i.e., saddle shape) would mitigate wafer bow along the y direction, but would increase wafer bow along the x direction.

Disclosed herein are techniques to deposit films on the backside of the wafer that cause anisotropic stress across the wafer from the backside such that the overall wafer bow may be controlled. Such films, when viewed along an x-direction, may have an internal compressive stress near the center of the wafer while having an internal tensile stress near the edge of the wafer, or vice versa. Such films, when viewed along a y-direction, may have an internal compressive stress from center-to-edge or an internal tensile stress from center-to-edge. When deposited on the backside of a wafer such films may reduce wafer bow that is inequal along x and y directions. While such techniques are obviously applicable to wafers having a positive y-bow and negative x-bow, or vice versa, techniques disclosed herein may be applied to various wafer bow shapes that have a different magnitude or sign of bowing in one principal direction than the other principal direction, or wafers having no bow. For example, the techniques disclosed herein may be applied to the wafer having a certain shape of bow caused by the frontside deposition. For another example, the backside of the bare wafer having no frontside deposited layers or the wafer having no or minimal bow may be processed with the techniques disclosed herein preemptively before bow is generated due to the frontside deposition.

Anisotropic internal stress may be accomplished by depositing curved bar profile and curved channel profile films on a wafer. A curved bar profile film and a curved channel profile film may have different internal stresses, resulting in a stacked film that has an anisotropic internal stress, i.e., the internal stress changes based upon the direction. As an example, FIGS. 3A-C illustrate curved bar and curved channel profile films. FIG. 3A is a bottom-side view of a wafer 306 having a center zone 304 and edge zones 302. FIGS. 3B and 3C present a side view and exploded side view, respectively, along the x direction of the wafer 306 having a curved bar profile film 308 and a curved channel profile film 307. A frontside layer 305 may be deposited on the frontside (or top) of wafer 306, causing a wafer bow that is compensated by films 307 and 308 deposited on a backside (or bottom) of the wafer 306. A film may be deposited on the backside of the wafer such that the film is substantially deposited in either center zone 304 or edge zones 302. This may be accomplished by a showerhead that is configured to substantially deposit in center zone 304 or edge zones 302. In some embodiments, a showerhead pedestal (or shoped) may be used for such deposition. In some embodiments, a shoped may be configured to deposit in such zones by, e.g., control of reactant gas flow in zones of the shoped that correspond to the zones of FIG. 3A. Such zones are schematically illustrated in FIG. 3A for illustration purposes only; a shoped or wafer may be considered having any different numbers, shapes, and configurations of zones.

Referring back to FIGS. 3B and 3C, a film deposited substantially in center zone 304 may have curved bar profile 308, while a film deposited substantially in edge zones 302 may have curved channel profile 307. That is, for example, a compressive stress film (307) may be deposited more in edge zones 302 (e.g., is thicker) compared to in center zone 304, while a tensile stress film (308) may be deposited more in the center zone 304 (e.g., is thicker) compared to in edge zones 302. While films may be deposited substantially in either center zone 304 or edge zones 302, it should be understood that some deposition may occur across the wafer and in the other zone. Furthermore, the shapes of the curved bar profile and curved channel profile are mere examples and variations in profile shape may occur. In some embodiments, center zone 304 may also be referred to as a curved bar profile deposition zone. In some embodiments, edge zones 302 may also be referred to as a curved channel profile deposition zone. In some other embodiments, center zone 304 may be referred to as a curved bar profile deposition zone, and edge zones 302 may be referred to as a curved channel profile deposition zone.

The curved bar profile film 308 has a decreasing thickness along an x direction from center to edge of wafer 306 and a uniform, or substantially uniform, thickness along a y direction of the wafer. Conversely, the curved channel profile film 307 has an increasing thickness along the x direction from center to edge of wafer 306 and a uniform, or substantially uniform, thickness along a y direction of the wafer. Together, curved bar profile film 308 and curved channel profile film 307 may form a uniform thickness profile film.

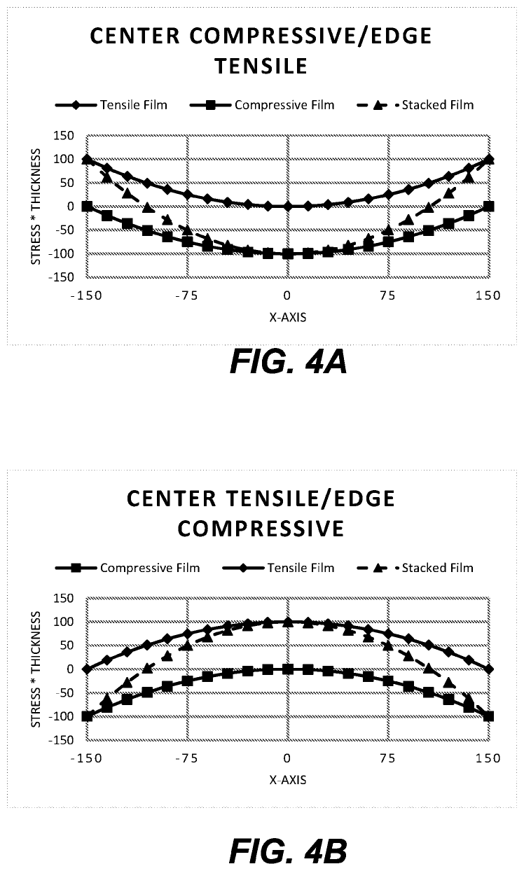

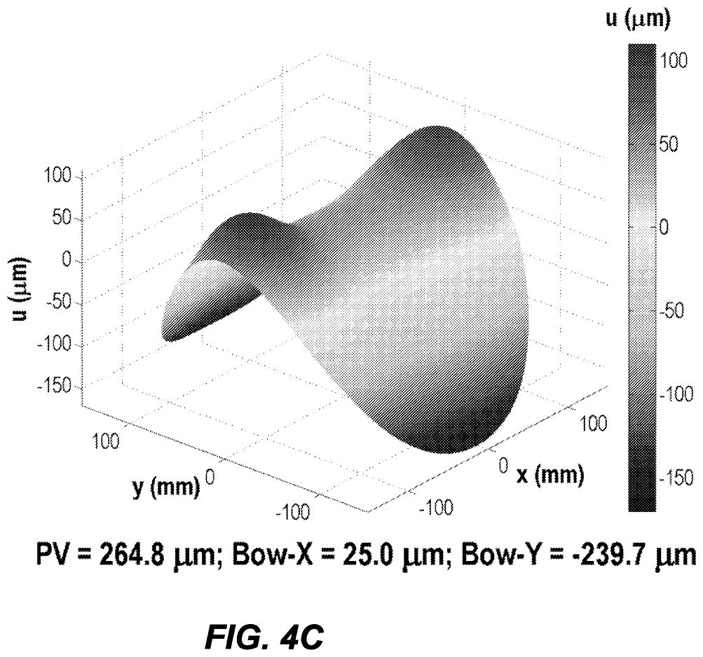

As film 307 and film 308 are deposited independently, each film may be deposited under conditions to have a different internal stress. For example, curved bar profile film 308 may have a compressive internal stress, while curved channel profile film 307 may have a tensile internal stress, or vice versa. As film stresses may be superimposed, the stacked film may have a compressive internal stress in areas of the film having a small x/large y coordinate, i.e., corresponding to center zone 304, while the stacked film also has a tensile internal stress in areas of the film having a large x/small y coordinate, i.e., coordinating to edge zones 302, or vice versa. As noted above, the center of the wafer may be considered the origin, e.g., x=0 and y=0. This anisotropic internal stress is explained further in reference to FIGS. 4A-B, below.

While films 307 and 308 are discussed herein as having opposite types of internal stress, e.g., one film has a compressive internal stress and the other film has a tensile internal stress, in some embodiments both films may have a tensile or compressive internal stress, but different magnitudes of internal stress. This may address wafers that have different magnitudes of x-bow and y-bow even if the both bows are positive or negative. In some embodiments depositing same type stress films may increase throughput.

In some embodiments, as the wafer bow to be compensated by the backside layers increases, the film thickness may also increase, as a thicker film may generally compensate greater wafer bow. However, greater thicknesses also increase the risk of cracking. Backside films having an internal tensile stress are more prone to cracking as backside films are typically brittle. Thus, in some embodiments a tensile film is deposited prior to a compressive film, as the compressive film deposited on the tensile film will partially counteract the internal tensile stress and reduce the risk of cracking. However, at greater thicknesses of the backside films, the internal stress may still cause the film to crack. For example, a single stack of complementary profile films may exhibit cracking at a total film thickness of 1.25 um. Cracking is undesirable as it may reduce the wafer bow compensation of the layer as well as cause defects and potential etching during later fabrication operations and even contaminate and/or damage the processing chamber.

To address this concern, an alternating stack film may be used that has a higher film cracking margin compared to an equivalent thickness single stack film. In some implementations, an alternating stack of films may be deposited, where each other film has a curved channel profile or a curved bar profile. FIGS. 3D-3G present various implementations for an alternating stack of backside films having complementary profiles on a substrate 306 having one or more frontside layers 305. In FIG. 3D, films 307 and 308 are alternated to form an alternating stack film 340 having films 308-1, 308-2, 308-3, and 308-N and films 307-1, 307-2, 307-3, and 307-M. In some embodiments, N=M, i.e., an alternating stack has an equal number of curved bar profile films and curved channel profile films. In other embodiments, N!=M, such that there are more or fewer curved bar profile films than curved channel profile films.

The alternating stack film 340 may compensate greater amounts of wafer bow from frontside layers than a single stack of a curved channel profile film a curved bar profile film may compensate alone. For example, a single stack of complementary profile films may crack at thicknesses of about 1.25 μm, which would compensate for about 250 μm of wafer bow. An alternating stack film having a total thickness of 1.25 μm may similarly compensate about 250 μm of wafer bow, but with a reduced risk of cracking. An alternating stack film may reduce throughput due to depositing multiple complementary layer stacks rather than a single complementary film stack, and thus typically would be undesirable. However, the improved material properties of an alternating film stack provide the numerous benefits discussed herein, including a higher cracking margin and improved thermal stability. In some embodiments, an alternating stack film 340 may comprise two or more sets of complementary profile films, e.g., two or more sets of a curved bar profile film 308 and a curved channel profile film 307.

In some embodiments, each of the curved bar profile films 308-1-N and curved channel profile films 307-1-M have the same profile, respectively. In other embodiments, the profiles of one or more non-uniform thickness profile film may be different from the other non-uniform thickness profile films. In some embodiments, a complementary profile film stack may be defined by a thickness 350, which refers to the thickness of the complementary profile film stack (e.g., a combination of a curved bar profile film and a curved channel profile film). A thickness 350 of the complementary profile film stack may be less than about 1 μm or between about 0.5 μm and about 1 μm. In some embodiments, each complementary film stack in an alternating film stack may have the same thickness, which for a four-bilayer stack shown in FIG. 3D may have a total thickness between about 2 μm and about 4 μm. In some embodiments, each complementally profile film stack in an alternating stack may have different thickness.

FIG. 3D presents an illustration where a curved bar profile film 308 is deposited after a curved channel profile film 307 is deposited, which is then repeated four times to provide an alternating stack of 4 complementary profile films. FIG. 3E presents a similar stack except that a curved bar profile film 308-1 is deposited before a curved channel profile film 307-1 is deposited, instead of after. As described above, the number of layers and the thickness profiles illustrated in these figures are exemplary only. More or less than four pairs of the complementary films are deposited to optimize the overall bow of the wafer. And, additional tensile or compressive layer may be added, in between the pair of the complementary films, or as the last layer, as illustrated in FIGS. 3F and 3G.

FIGS. 3F and 3G present illustrations of cap or filler layers that may be deposited. In FIG. 3F, a cap layer 342 that has a uniform, or substantially uniform, thickness is deposited. As will be discussed further below, cap layer 342 may be a uniform thickness profile film having a tensile internal stress, a compressive internal stress, or zero or negligible internal stress. A uniform thickness profile film may be deposited after depositing one or more stacks of complementary profile films. In some embodiments, a uniform thickness profile film may be deposited between pairs of the stacks of complementary profile films. For example, complementary profile films as described herein may be used to compensate for saddle-shaped wafer bow, e.g., a positive x-bow and negative y-bow. While complementary profile films may reduce the difference in wafer bow between the x-direction and y-direction, the wafer bow from a reference plane (e.g., an xy plane intersecting the wafer) may still be relatively large, e.g., 200 μm or more. For example, a saddle-shaped wafer may have backside layers deposited thereon that change the shape to a bowl or dome shaped wafer. The difference between x-bow and y-bow is reduced, but the wafer is still bowed. A uniform thickness profile cap layer may compensate for such a wafer bow by having a uniform tensile internal stress or compressive internal stress. As the x-bow and y-bow have been substantially equalized by the complementary profile films, the uniform thickness profile film may thus compensate the remaining wafer bow.

FIG. 3G presents an illustration of a filler layer 344. During deposition of a curved bar profile film 308, a curved bar profile film may have a “center drop,” where the thickness of the film has two maxima offset from a center position of the film at or near radius zero (i.e., at or near the wafer center), and at radius zero the thickness of the film is less than the maxima. This difference in thickness may be insubstantial for small thicknesses of complementary profile films, e.g., less than about 1 μm. However, for larger thicknesses of the complementary profile films or an alternating stack of complementary profile films having a large overall thickness, e.g., greater than about 2 μm or greater than about 2.5 μm, the center drop may become noticeable and affect the flatness of the film. Thus, a filler layer 344 may be deposited to fill the gap formed in the curved bar profile film. In some embodiment, a filter layer 344 may be deposited to fill the gap formed in the curved channel profile film, for example, where the alternating stack film 340 is formed similarly to that of FIG. 3D. Filler layer 344 may be deposited using similar techniques as curved bar profile 344 with a sharper taper in thickness as a function of radius.

An alternating stack of films may have various advantages over a single stack. As noted above, an alternating stack of films has a higher cracking margin. This may result from the compressive stress film applying a compressive stress on the tensile stress films, reducing the internal tensile stress at the exterior edge of the tensile stress film and thus reducing the risk of cracking.

An alternating stack of films may also have improved thermal stability. Backside layers such as silicon nitride may have a stress shift under thermal annealing conditions, e.g., during fabrication processes performed at about 600° C. or higher. A stress shift is the change in internal stress of a film, typically after annealing, which is generally undesirable as it may reduce the effectiveness of films to compensate wafer bow or increases the risk of cracking. This stress shift may result from unreacted species in the film, such as hydrogen and nitrogen, which may be present in Si—H or N—H bonds from precursors and reactants such as silanes and NH₃. Under annealing conditions these bonds may react and the hydrogen and/or nitrogen may diffuse to the surface, leaving the film and changing the internal stress. For a single bilayer film of complementary profile films, increasing the overall thickness may increase the percent stress shift following an anneal operation. However, an alternating stack of films may not increase the percent stress shift. This may be due to the alternating layers limiting diffusion of species from the films, where each interface of compressive and tensile films may limit diffusion of hydrogen and other species and thus limit the stress shift of the films.

For example, a 0.5 μm thick complementary profile film stack may have a stress shift following an anneal at 800° C. for 30 minutes that decreases the wafer bow compensate by the film stack by about 20%. A 2.5 μm thick complementary profile film stack may have a stress shift from the same operation of about 38%, which is undesirable as a greater stress shift requires a thicker film to properly compensate the wafer bow after annealing, which decreases throughput. An alternating stack film as disclosed herein, however, may have about 20% or less wafer bow compensation loss from an internal stress shift for overall thicknesses between about 1 μm and about 2.5 μm, where each complementary bilayer may have a thickness of about 0.5 μm. Thus, in some embodiments, the stress shift does not depend on the overall thickness of an alternating stack, but on the thickness of individual non-uniform thickness profile films, such that an alternating stack may compensate a greater wafer bow without a greater loss in wafer bow compensation after annealing. In various embodiments, annealing may be performed at temperatures greater than about 650° C., greater than about 700° C., greater than about 800° C., greater than about 900° C., or between about 650° C. and about 900° C. An alternating stack film as described herein may have a stress shift following annealing that changes the wafer bow compensation by about 20% or less.

FIGS. 4A-B provide graphs of internal stress times thickness for two films along a x-axis measured from center-to-edge of a wafer. In FIG. 4A, the tensile film is deposited with a curved channel profile, while the compressive film is deposited with a curved bar profile. The stacked film has an internal stress based on the combination of the two films, and thus has a compressive stress (negative values in FIG. 4A) for small x-values (e.g., about up to 100 mm along the x-axis from the center) and a tensile stress (positive values) for large x-values (e.g., from about 100 mm to the edge of the wafer along the x-axis).

FIG. 4B shows a different combination of films, where the tensile film is deposited with a curved bar profile, while the compressive film is deposited with a curved channel profile. The stacked film has an internal stress based on the combination of the two films, and thus has a tensile stress (positive values in FIG. 4B) for small x-values (e.g., about up to 100 mm along the x-axis from the center) and a compressive stress (negative values) for large x-values (e.g., from about 100 mm to the edge of the wafer along the x-axis). The result of the stacked film is an anisotropic internal stress that changes across the x-and y-directions of the film, as shown for the x-axis in FIGS. 4A and 4B.

In various embodiments, two films may be deposited according to the graphs of either FIG. 4A or 4B. In some embodiments, additional backside layers may be deposited. The graphs of FIGS. 4A and 4B are examples, and films as-deposited may have stress profiles that vary from those shown. For example, as discussed further herein, the internal stresses of both films may be controlled based upon the identified amount of bowing/internal stress of a wafer.

FIG. 4C provides an isometric view of a wafer bow based on backside deposition of a stacked film having an internal stress profile similar to that shown in FIG. 4B. The tensile film is deposited with a curved bar profile, while the compressive film is deposited with a curved channel profile. The stacked film has an internal stress based on the combination of the two films, and thus has a tensile stress for small x-values and a compressive stress for large x-values. Put another way, the wafer of FIG. 4C has a positive x-bow resulting from internal compressive stress along the x-direction, and a negative y-bow resulting from internal tensile stress along the y-direction.

It should be understood that the wafer bow shown in FIG. 4C is for a substantially flat wafer upon which backside layers corresponding to FIG. 4B were deposited on the backside. In typical usage, an incoming wafer would be bowed based upon internal stress from frontside layers, and the wafer bow shown in FIG. 4C would be to counteract already existing bowing to achieve a relatively flat shape. For example, the stacked film shown in FIGS. 4B and 4C may be used to counteract a −X/+Y wafer bow shape as shown in FIG. 2.

As shown in FIG. 4C, compressive internal stress in a center zone for small y-values causes the wafer to have a positive x-bow, while tensile internal stress in edge zones for large y-values causes the wafer to have a negative y-bow. This anisotropic internal stress allows the stacked film to mitigate bowing of a saddle-shaped wafer to achieve a substantially flat wafer.

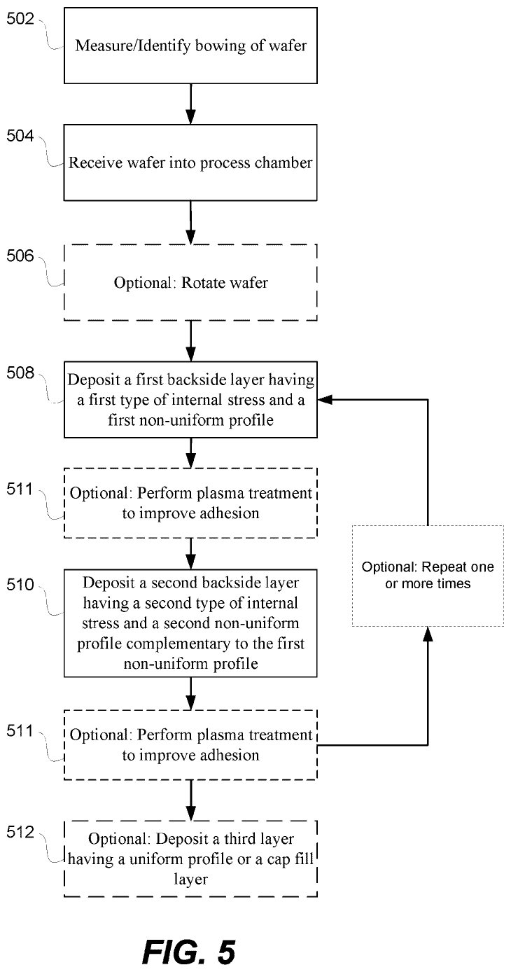

FIG. 5 shows an example process using deposition of a backside layer structure including two or more films have non-uniform thickness profiles. The process of FIG. 5 starts with measuring and/or identifying bowing of a wafer (502). The wafer may have one or more frontside layers deposited thereon, and one or more backside layers deposited thereon, that cause bowing of the wafer. Measuring and/or identifying the wafer bow may include measuring or determining the shape of the wafer as well as which dimension has a larger bow. In some embodiments, measuring and/or identifying the wafer bow may include measuring and/or identifying x-bow and y-bow values. In some embodiments, measuring and/or identifying wafer bow may include measuring and/or identifying whether the x-bow is greater or lesser than the y-bow.

After measuring and/or identifying wafer bowing, the wafer is received into a process chamber (504). In some embodiments, measuring and/or identifying wafer bow may be performed as part of receiving the wafer into the process chamber or after receiving the wafer into the process chamber. In some embodiments the wafer may be optionally rotated as part of or after receipt into the process chamber (506). Rotation may be performed to orient the wafer such that the wafer bow is aligned to deposition zones of the process chamber as discussed above in connection with FIG. 3A. For example, a process chamber may be configured to deposit a tensile film in the center zone and a compressive film in edge zones. Thus, an incoming wafer may be rotated so that, between the x-bow and the y-bow of the wafer, the positive dimensional bow is aligned with a center zone of the process chamber (as a tensile internal stress film deposited on a wafer backside will mitigate positive bow). In some embodiments, the incoming wafer may be rotated so that the more positive wafer bow is aligned with the center zone of the process chamber. In some embodiments, a process chamber may be configured to deposit a curved bar profile tensile film and a curved channel profile compressive film. For example, a process chamber may deposit a curved bar profile tensile film and a curved channel profile compressive film having better material properties, e.g., better non-uniformity, than other combinations of non-uniform thickness profile films and internal stresses. Thus, rotating wafers to align the wafer bow with the deposition zones of the process chamber may improve throughput and reduce non-uniformities compared to performing different recipes for wafers having +X/−Y bow and wafers having −X/+Y bow.

For example, returning to FIG. 2, if the process chamber is configured to deposit a curved bar profile tensile film in a center zone and a curved channel profile compressive film in edge zones, then a −X/+Y saddle shape would not need to be rotated, while a +X/−Y saddle shape would be rotated. Rotation would ensure the positive bow is aligned with the curved bar profile tensile film and the negative bow is aligned with the curved channel profile compressive film. In effect, rotating 90° a wafer having a +X/−Y wafer bow saddle shape would result in a wafer having a −X/+Y wafer bow saddle shape, assuming the coordinates are relative to the deposition apparatus rather than the wafer itself.

As discussed further below, in some embodiments rotation may be optional as the process chamber may be able to deposit the curved bar profile films and curved channel profile films as having a compressive or tensile internal stress. Thus, depending on a wafer's x-bow and y-bow the internal stress of the deposited films may be changed to properly compensate the x-bow and y-bow. Notably, however, in some embodiments a process chamber may not be azimuthally symmetrical; the curved bar profile and curved channel profiles may not rotate and instead have a fixed orientation, e.g., the orientation shown in FIG. 3A.

A first backside layer having a first type of internal stress and a first non-uniform thickness profile is deposited (508). The first type of internal stress may be either compressive or tensile. The non-uniform thickness profile may be either a curved bar profile or a curved channel profile as discussed herein, or may be any other variation or combination of such profiles. The type of internal stress and the profile of the film may be based upon the wafer bow. For example, a +X/−Y wafer bow saddle shaped wafer may have a curved channel profile tensile film or a curved bar profile compressive film deposited thereon to compensate for the positive x-bow or negative y-bow, respectively.

Alternatively, the wafer may be rotated 90° such that the wafer effectively has a −X/+Y wafer bow saddle shape. In such an embodiment, a curved channel profile compressive film or a curved bar profile tensile film may be deposited thereon to compensate for the (now) negative x-bow or positive y-bow, respectively.

A second backside layer having a second type of internal stress and a second non-uniform thickness profile complementary to the first non-uniform thickness profile is deposited (510). In some embodiments, the second type of internal stress is the opposite type of the first internal stress, i.e., compressive or tensile stress. The second non-uniform thickness profile may be complementary to the first non-uniform thickness profile, i.e., if the first non-uniform thickness profile is a curved bar profile, the second non-uniform thickness profile is a curved channel profile. In some embodiments, a second backside layer may not be complementary to the first second backside layer, or partially complementary to the first backside layer.

Generally, a tensile film pulls a positive bow to a more planar shape, while a compressive film would push a negative bow to a more planar shape. Furthermore, a curved bar profile film will compensate y-bow, while a curved channel profile film will compensate x-bow, as the curved bar profile film substantially deposits in a center zone and the curved channel profile film substantially deposits in edge zones, as shown, for example, in FIG. 3A. Thus, based on the x-bow and y-bow of the incoming wafer, complementary films may be deposited to properly address the x-bow and y-bow. Depending on which wafer bow was addressed by the first backside layer, the second backside layer may be formed to address the other wafer bow, e.g., x-bow or y-bow.

In some embodiments, an optional plasma treatment may be performed to improve adhesion of the backside layers to the substrate (511). The plasma treatment may improve adhesion of the curved bar profile and curved channel profile films to underlying layers and/or substrate. This operation may be performed between depositing each of the first and second backside layers, after depositing the first backside layer or after depositing the second backside layer, or may not be performed at all or may be performed more than once. In some embodiments, a plasma treatment may be performed using an inert gas, e.g., argon, xenon, N₂, etc. In some embodiments, the plasma treatment is performed using an inert gas and substantially no other gas. The plasma treatment may bombard the surface, improving adhesion without etching the layers.

In some embodiments, operations 508 and 510 and optional operation 511 may be repeated one or more times. Operation 511 may be optionally performed for any one or more of each cycle of depositing complementary profile films. These operations may be repeated to deposit an alternating layer stack as shown in FIGS. 3D-G. In some embodiments, each pair of complementary profile films may have a thickness less than about 1 μm, where an alternating stack of films may have a total thickness greater than about 1 μm, greater than about 2 μm, greater than about 3 μm, or between about 1 μm and about 3 μm. An alternating stack of films may generally decrease throughput compared to a single stack of complementary profile films. However, an alternating stack of films may have improved material properties, including cracking margin, thermal stability, adhesion, substrate surface protection, and film uniformity.

Optionally, in some embodiments a third layer having a uniform thickness profile, curved channel profile, or a curved bar profile is deposited (512). In some embodiments, the first and second backside layers may equalize the x-bow and y-bow, however some bowing may still be present. In such embodiments, the wafer may have a bowl or umbrella shape. Thus, depositing a uniform thickness profile film may help further reduce the wafer bow. In some embodiments, an isotropic internal stress film is deposited, e.g., a tensile film or compressive film, to further mitigate wafer bow. The type of internal stress and the magnitude of the internal stress may be based upon the wafer bow. A positive wafer bow, or bowl shape, may be mitigated with a tensile film, while a negative wafer bow, or dome/umbrella shape, may be mitigated with a compressive film.

In some embodiments, the magnitude of the bowing of a wafer after depositing the first backside layer and the second backside layer may be relatively large and thus a third film may be deposited to mitigate such bowing. For example, an incoming wafer may have an x-bow of 400 μm and a y-bow of −400 μm, and the x-bow and y-bow after depositing the first backside layer and the second backside layer may be −300 μm. While the x-bow and y-bow are still large, they have been equalized and thus may be mitigated by a uniform thickness profile backside layer deposition. The first backside layer and second backside layer may thus equalize the x-bow and y-bow but not mitigate the bow within an acceptable tolerance.

In some embodiments, the magnitude of the internal stress of the deposited first and second backside layers may be less than the magnitude of the internal stress of the deposited frontside layer; i.e., the first and second backside layers does not fully compensate the bow induced by the frontside layer(s). In some embodiments, a stack of the first and second backside layer reduces the bow of the wafer to about 200 μm or less.

In some embodiments, a cap layer or a filler layer (collectively, cap fill layer) is deposited in 512. The cap fill layer may be deposited to improve the flatness of the backside of the substrate and/or the overall wafer bow. As noted above, a curved bar profile film may have a “center drop,” where the thickness of the film has two maxima offset from a center position of the film at radius zero, and at radius zero the thickness of the film is less than the maxima. This difference in thickness may be insubstantial for small thicknesses of complementary profile films, e.g., less than about 1 μm. However, for larger thicknesses of the complementary profile films or an alternating stack of complementary profile films having a large overall thickness, e.g., greater than about 2.5 μm or greater than about 3 μm, the center drop may become noticeable and affect the flatness of the film.

Thus, in some embodiments, a curved bar profile film is deposited in 512 as a cap fill layer. A cap fill layer may be any material disclosed herein, including silicon nitride or silicon oxide. In some embodiments, the cap fill layer may have a neutral or substantially neutral internal stress. The cap fill layer may be deposited to improve flatness of the backside layer stack, and thus a neutral or zero internal stress may be desirable to not affect the internal stress of the backside layers and overall wafer bow.

In some embodiments, operation 512 is not performed. In such embodiments a uniform backside film is not deposited as the wafer is substantially flat after depositing the first and second backside layers. This may result from tuning the first and second backside layers based upon the wafer's x-bow and y-bow. The first and second backside layers may thus fully compensate the wafer bow without a third, uniform layer. For example, the magnitude of the tensile stress and/or compressive stress of a backside layer may be controlled by tuning of the deposition conditions, e.g., radio-frequency power, including high frequency and low frequency power, temperature, pressure, precursor flow, reactive gas flow, ratios of precursor flow, dopants, as well as the thickness of the deposited films. In some embodiments, the process conditions may be altered to tune the magnitude of the tensile or compressive stress of the backside layers to substantially mitigate the x-bow and y-bow of an incoming wafer. Thus, depositing the first backside layer and second backside layer as discussed above may substantially mitigate all wafer bow. In such embodiments, a third, uniform backside layer may not be needed to mitigate the incoming wafer bow.

In some embodiments, operation 512 may not be performed based upon the shape of the incoming wafer. For example, a taco or half pipe shaped wafer may have minimal or no bowing in the x- or y-direction. Thus, only the x-bow or y-bow needs to be mitigated, but not both. In such embodiments the curved bar profile film and curved channel profile film may be tuned to compensate for either of the x-bow or y-bow. The two non-uniform thickness profile films may equalize the bows by mitigating either of the x-bow or y-bow without causing bowing in the other, substantially flat direction.

The backside layers may be deposited using CVD, PECVD, ALD, epitaxy, PVD, or other deposition process. The backside layers may be deposited using a special purpose backside deposition apparatus. In some embodiments, the wafer switches chambers between operations 508, 510, and/or 512. The backside deposition apparatus may be a different deposition apparatus then the apparatus used to deposit the one or more frontside layers.

The bow induced by the first, second, and third backside layers may be the sum of the individual induced bows. In some embodiments, bow magnitude of the combined backside layers may be about the same as the bow magnitude of the one or more frontside layers. In some embodiments, the x-bow and y-bow magnitude of the combined backside layers may be about the same as the x-bow and y-bow magnitude of the one or more frontside layers. In some embodiments, the bow contributions of all frontside and backside layers may combine so that the total bow of the wafer is minimal (i.e., less than about 100 μm). In some embodiments, after performing the method of FIG. 5, the wafer may be substantially flat, e.g., the wafer has a bow of about 200 μm or less, about 150 μm or less, about 100 μm or less, about 50 μm or less, or about 30 μm or less. The degree of flatness may depend on the particular downstream operations to be performed. For example, deposition or etch operations may be within tolerance with a wafer bow of about 200 μm or less, about 150 μm or less, about 100 μm or less. Lithography operations, however, may have a stricter tolerance and substantially flat may be about 50 μm or less, or about 30 μm or less.

Note that references to bow values induced or caused by individual backside layers assume that the bow is uncompensated by other layers. For example, when referring to the magnitude of a bow caused by a first backside layer, we assume that is the bow that would be produced on the substrate if no other layers were present, e.g., no frontside layers. The magnitude of a bow induced by a layer depends on both the internal stress of the material in the layer and the thickness of the layer.

Compensation by backside layers refers to bow contributions of backside layers that may combine with bow contributions of frontside layers to reduce or equalize x-bow and y-bow. As noted above, bow contributions of all frontside and backside layers may be combined. A positive bow cause by frontside layers, forming a bowl shape, may be reduced by a backside layer having a tensile internal stress that causes a negative bow. The negative bow caused by the backside layer compensates the positive bow caused by the frontside layers, resulting in a total bow of the wafer that is smaller and/or more uniform than without the backside layers. Curved bar profile films and curved channel profile films may compensate either x-bow or y-bow depending on the orientation of the process chamber and the wafer. For example, assuming the backside layers are deposited in zones according to FIG. 3A, a curved bar profile film may compensate y-bow, e.g., reducing the total y-bow, while a curved channel profile film may compensate x-bow, e.g., reducing the total x-bow. In some embodiments, compensation may include partially mitigating wafer bow. As noted above, a first backside layer and second backside layer may partially compensate wafer bow, and a third backside layer, or any more numbers of layers, may be deposited to compensate any remaining wafer bow. In other embodiments, a first backside layer and a second backside layer having non-uniform thickness profiles as described herein may fully compensate wafer bow, e.g., reduce wafer bow to less than about 100 μm or less than about 30 μm.

In certain embodiments, backside layer disclosed herein comprise a material having an intrinsic internal stress, which has a magnitude of at least about 100 MPa or about 100 to about 2000 MPa. These values may be for tensile or compressive internal stress, as the case may be for the type and properties of backside material needed to counteract bow caused by the frontside layer(s). The above-recited internal stress values may apply to any one or more backside layers in a multilayer backside stack. Any two backside layers may have the same or different values of internal stress.

Example materials used to make backside layers having tensile internal stress include silicon nitrides (SiN), silicon oxynitrides, and polymer layers. As examples, tensile films can be deposited using CVD or PECVD techniques. To combat wafer bow caused by a frontside layer with a compressive internal force, a compressive film may be used for the bulk backside layers. Compressive films may be formed using specific materials and/or processing conditions. Example materials used to make compressive films include silicon oxides (SiOₓ), silicon nitrides, aluminum oxides, aluminum nitrides, and polysilicon. Compressive films can be deposited using CVD or PECVD techniques. The above-recited materials and deposition techniques may apply to any one or more backside layers in a multilayer backside stack. Any two backside layers may be formed by the same or different techniques.

Deposition by PECVD may proceed by flowing a reactant into a process chamber, and optionally with a co-reactant, while exposing the bowed semiconductor substrate to plasma. The plasma may drive a gas phase reaction that results in deposition of film. The PECVD reactions may generally involve delivering reactant(s) to the semiconductor substrate continuously while the semiconductor substrate is exposed to plasma. In some embodiments, depositing a nitride film on the backside of the substrate includes exposing the backside of the flat and/or bowed semiconductor substrate to a silicon-containing precursor and a nitrogen-containing reactant, and exposing the backside of the semiconductor substrate to plasma to drive a reaction between the silicon-containing precursor and the nitrogen-containing reactant to deposit the nitride film. To protect the frontside of the semiconductor substrate on which circuits, transistors, and other device components are patterned during the backside processes, the frontside is protected from being exposed to plasma and/or reactant or process gases, for example, by keeping the gap between the frontside of the semiconductor substrate and the showerhead to less than plasma sheath and/or by flowing inert gas(es) onto the frontside of the semiconductor substrate. By depositing on the backside of the semiconductor substrate, the nitride film avoids being deposited on circuits, transistors, and other device components on the frontside of the bowed semiconductor substrate.

In some embodiments, the curved bar profile and curved channel profiles described herein may be achieved by controlling precursor concentration adjacent to the bowed semiconductor substrate during deposition. In the present disclosure, precursor concentration adjacent to the bowed semiconductor substrate may be controlled by design features in a showerhead pedestal. Such design features may influence flow dynamics of the precursor from the showerhead pedestal. In some implementations, the showerhead pedestal may be divided into multiple zones as shown in FIG. 3A. For example, precursor gas may be delivered in a first zone and dilution gas may be delivered in a second zone, and/or different flow rates or concentrations of precursor and dilution gas may be delivered to different zones to control the thickness and/or properties of the films deposited in different zones. This modulates the concentration of precursor gas adjacent to the bowed semiconductor substrate. In some implementations, the precursor gas may be delivered via a first supply tube and the dilution gas may be delivered via a second supply tube.

### Apparatus

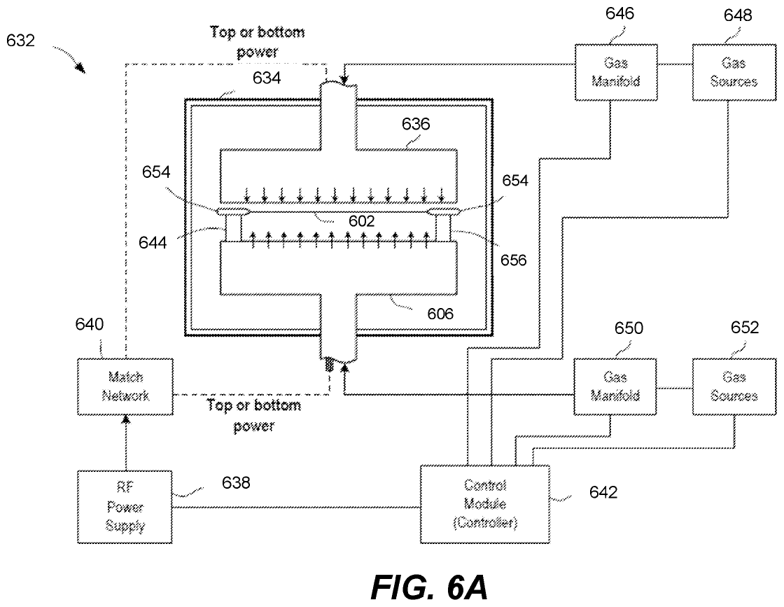

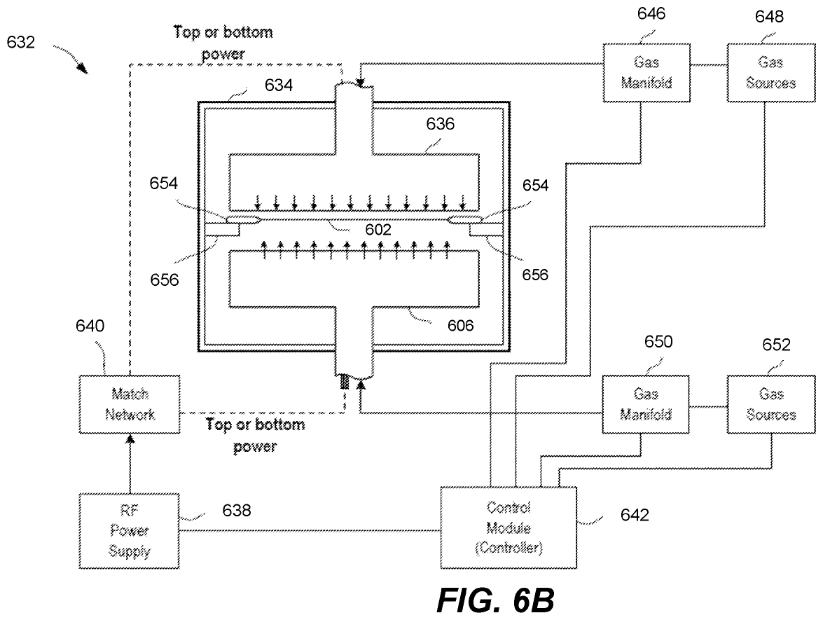

In some embodiments, FIG. 6A is a block diagram that illustrates a substrate processing system 632 used to perform processing on a wafer 602, according to some embodiments. As shown, the substrate processing system may include a processing chamber (or a chamber) 634. A center column may be configured to support a pedestal for when a top surface (or a frontside) of the wafer 602 is being processed, e.g., a film is being formed on the top surface of the wafer 602, or on the backside of the wafer 602. The pedestal, in accordance with some embodiments disclosed herein, may be referred to as a showerhead pedestal (“ShoPed”) 606. A showerhead 636 may be disposed over the ShoPed 606.

In some embodiments, the showerhead 636 may be electrically coupled to power supply 638 via a match network 640. The power supply 638 may be controlled by a control module 642, e.g., a controller. In some embodiments, power may be provided to the ShoPed 606 instead of the showerhead 636, or power may be provided to both the ShoPed 606 and the showerhead 636. The control module 642 may be configured to operate the substrate processing system 632 by executing process input and control for specific process recipes. Depending on whether the top surface of the wafer 602 is receiving a deposited layer or layer stack or the bottom surface of the wafer 602 is receiving a deposited layer or layer stack, the controller module 642 may set various operational inputs for a process recipe, such as power levels, timing parameters, process gasses, mechanical movement of a wafer 602, and/or the height of the wafer 602 relative to the ShoPed 606 (and the distance between the wafer 602 and the showerhead 636).

In some embodiments, the center column may also include lift pins, which are controlled by a lift pin control. Such lift pins may be used to raise the wafer 602 from the ShoPed 606 to allow an end effector (not shown) to pick the wafer and to lower the wafer 602 after being placed by the end effector. The end effector may also place the wafer 602 over spacers 644. As will be described below, the spacers 644 may be sized to provide a controlled separation of the wafer 602 between a bottom surface of the showerhead 636 (facing the wafer) and a top surface of the ShoPed 606 (facing the wafer).

In some embodiments, the substrate processing system 632 may further include a first gas manifold 646 that is connected to first gas sources 648, e.g., gas chemistry supplies from a facility and/or inert gases. Depending on the purposes and processing being performed over a top surface of the wafer 602, the control module 642 may controls the delivery of first gas sources 648 via the first gas manifold 646. The chosen gases may then be flown into the showerhead 636 and distributed in a space volume defined between a face of the showerhead 636 that faces that wafer 602 when the wafer is resting over the pedestal or ShoPed.

In some embodiments, the substrate processing system 632 may further include a second gas manifold 650 that is connected to second gas sources 652, e.g., gas chemistry supplies from a facility and/or inert gases. Depending on the processing being performed over a bottom surface of the wafer 602, the control module 642 may control the delivery of second gas sources 652 via the second gas manifold 650. The chosen gases may then be flown into the showerhead 636 and distributed in a space volume defined between a face of the ShoPed 606 that faces an under surface or under side (e.g., backside) of the wafer 602 when the wafer is resting over the ShoPed 606 and/or spacers 644. The spacers 644 may provide for a separation that optimizes deposition to the under surface of the wafer 602, while reducing deposition over the top surface of the wafer 602. In some embodiments, while deposition is targeted for the under surface of the wafer 602, an inert gas may be flown over the top surface of the wafer 602 via the showerhead 636, which may push reactant gases away from the top surface and enable reactant gases provided from the ShoPed 606 to be directed to the under surface of the wafer 602. Spacers 644 and/or other similar substrate support features may be used to provide controlled separation between the wafer and the ShoPed and the showerhead. Spacers 644 and/or other similar substrate support features may be connected or supported by the ShoPed such that the wafer (or its reference plane, when the wafer is bowed) may maintain an even and/or parallel distance from the top surface of the ShoPed, even when there is an unwanted movement or oscillation at the system or chamber level.

In some embodiments, either showerhead 636 or ShoPed 606, or both, may have a zonal deposition design similar to that shown in FIG. 3A. For example, gas manifold 650 may be fluidically linked to control the delivery of gases to either zones 302 or zone 304. By controlling the flow of gases to either zones 302 or zone 304 films may be deposited as shown in FIGS. 3B and 3C. In some embodiments, either showerhead 636 or ShoPed, or both, may have a zonal deposition design different from that shown in FIG. 3A. For example, with reference to FIG. 5, when the bowing of wafer is measured or identified (502), a showerhead and/or ShoPed that has corresponding zonal deposition design to that specific wafer may be used to deposit films to the backside of the wafer, or gas flows through a showerhead and/or ShoPed may be tuned to correspond to the profile of the wafer bow.

Further, the gases may be premixed or not. Appropriate valving and mass flow control mechanisms may be employed to ensure that the correct gases are delivered during the deposition and plasma treatment phases of the process. Process gases may exit the chamber 634 via one or more exhausts or outlets. A vacuum pump (e.g., a one or two stage mechanical dry pump and/or a turbomolecular pump) may draw process gases out and maintains a suitably low pressure within the reactor by a close loop-controlled flow restriction device, such as a throttle valve or a pendulum valve.

In some embodiments, a carrier ring 654 may encircle an outer region of the ShoPed 606. When the top surface of the wafer 602 is being processed, e.g., a material is being deposited thereon, the carrier ring 654 may be configured to sit over a carrier ring support region that is a step down from a wafer support region in the center of the ShoPed 606. The top surface of the carrier ring 654 is generally coplanar with the top surface of the wafer 602. The carrier ring 654 may include an outer edge side of its disk structure, e.g., outer radius, and a wafer edge side of its disk structure, e.g., inner radius, that is closest to where the wafer 602 sits. The carrier ring 654 may be associated with an inner diameter (ID). The inner diameter may extend to an inner perimeter of the carrier ring and generally surround a substrate (e.g., wafer 602) in a processing chamber. The wafer edge side of the carrier ring 654 may also include a plurality of contact support structures or “tabs” which may be configured to lift the wafer 602 when the carrier ring 654 is held by the spacers 644. The carrier ring 654 may include a plurality of tabs with a quantity selected from a range to support the wafer 602 during processing. Additional details regarding embodiments of the tabs will follow. In some embodiments, a wafer may be placed directly upon, or supported directly by, spacers or other similar substrate support features without a carrier ring.

FIG. 6B is a block diagram that illustrates another version of substrate processing system 632 used to perform processing on the wafer 602, according to some embodiments. In some embodiments, spider forks 656 may be used to lift and maintain the carrier ring 654 in its process height, e.g., to allow depositing in the under surface (backside) of the wafer 602. The carrier ring 654 may therefore be lifted along with the wafer 602. In some implementations, the carrier ring 654 may be rotated to another station, e.g., in a multi-station system. In some embodiments, a spider forks or any other transfer mechanism may be used to lift or move the wafer directly without a carrier ring.

Broadly speaking, the embodiments disclosed herein are for a system to deposit PECVD films on the selective side of the wafer (front and/or back) with dynamic control. Some embodiments may include a dual gas-flowing electrode for defining a capacitively-coupled PECVD system. The system may include a gas-flowing showerhead (e.g., showerhead 636) and a ShoPed 606. In some embodiments, the gas-flowing pedestal (i.e., ShoPed) is a combination of showerhead and pedestal, which enables deposition on a backside of the wafer. The electrode geometry combines features of a showerhead, e.g., a gas mixing plenum, holes, hole-pattern, gas jet preventing baffle, and features of a pedestal. Examples of features of a pedestal or ShoPed may include an embedded controlled heater (or distributed heater or heater elements), wafer lift mechanisms, ability to hold plasma suppression rings, and movability. This enables the transfer of wafers and the processing of gasses with or without RF power from the pedestal.

In some embodiments, the system may have a wafer lift mechanism that tightly controls parallelism of the substrates against the ShoPed, showerhead, and/or electrodes. In one example, this may be achieved by setting up the lift mechanism parallel to the two electrodes and controlling manufacturing tolerances, e.g., spindle or lift pins mechanisms. In another example, the lift may be achieved by raising the wafer lift parts. This option may not allow dynamic control of the side that gets deposited.

In some configurations, the lift mechanism may allow dynamically controlling the substrate position during processing (before plasma, during plasma, after plasma) to control the side of the deposition, profile of the deposition, and deposition film properties. The system may further allow selective enabling/disabling of the side where reactants are flown. One side can flow the reactant and the other side can flow inert gases to suppress the deposition and plasma.

In some embodiments, the gap between the side of the wafer that does not need plasma/deposition may be tightly controlled. This distance may be controlled to suppress plasma. By not controlling the distance, the wafer may be susceptible to plasma damage. For example, the system may allow a minimal gap from about 2 mm to about 0.5 mm, and in another embodiment from about 1 mm to about . 05 mm (limited by the wafer bow), and such gap can be controlled. The gap maybe controlled depending on process conditions.

In some embodiments, the gas-flowing pedestal (i.e., ShoPed) may enable, without limitation: (a) thermal stabilization of the wafer to processing temperature prior to processing; (b) selective design of hole patterns on the ShoPed to selectively deposition film in different areas of the backside of the wafer; (c) swappable rings can be attached to achieve appropriate plasma confinement and hole pattern; (d) stable wafer transfer mechanisms within chamber and for transferring wafer outside to another chamber or cassette-such as lift pins, RF-coupling features, minimum-contact arrays; (e) implement gas mixing features, e.g., such as inner plenum, baffle and manifold lines openings; and (f) add compartments in the gas-flowing pedestal (i.e., ShoPed) to enable selective gas flow to different regions of the back side of the wafer and control flow rates via flow controllers and/or multiple plenums.

In another embodiment, dynamic gap control using wafer lift mechanism enables: (a) control of the distance from deposition or reactant flowing electrode to the side of the wafer that needs deposition or in the middle so that both sides can be deposited; and (b) the lift mechanism to control the distance dynamically during the process (before plasma, during plasma, after plasma) to control the side of the deposition, profile of the deposition, and deposition film properties. In another embodiment, for a deposition mode used to deposit on the backside of the wafer, film edge exclusion control is highly desirable to avoid lithography-related overlay problems. The lift mechanism used in this system is done via a carrier ring 654 that has a design feature to shadow the deposition on the edge. This specifies the edge exclusion control via the design and shape of the carrier ring.

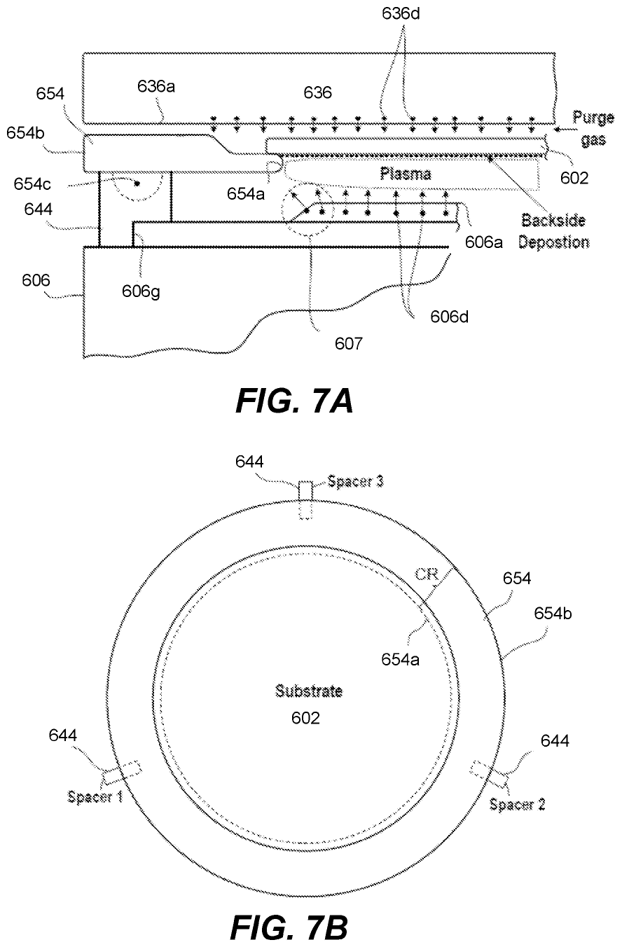

FIG. 7A shows a cross-sectional view of an edge region of the ShoPed 606. This view provides a cross-sectional representation of the carrier ring 654, which has a carrier ring inner radius 654a and a carrier ring outer radius 654b. In some embodiments, the carrier ring 654 includes support extensions 654c, which extend below the substantial flat surface of the carrier ring 654.

The support extensions 654c are configured to mate and sit within support surfaces defined into a top surface of the spacers 644. The support surfaces provide a complementary mating surface for the support extensions 654c, such that the carrier ring 654 is prevented from sliding or moving when supported by the spacers 644. Although three spacers are shown as spacers 644 are shown in FIG. 7B, it is envisioned that any number of spacers may be provided, so long as the carrier ring can be supported substantially parallel to the surface of the ShoPed 606, and spacing is defined for supporting wafer 602 at a spaced apart relationship from a top surface of the ShoPed 606.

Further shown is that a top surface of the ShoPed 606 will include a hole pattern 606a that is distributed throughout the surface to provide even distribution and output of gases during operation. In one embodiment, the hole pattern 606a is distributed in a plurality of concentric rings that start at the center of the top surface of the ShoPed 606 and extend to an outer periphery of the ShoPed 606. At least one hole pattern 606a is provided at an edge hole region 607 of the hole pattern, and orifices defined in the edge hole region 607 are preferably angled to provide gases non-perpendicular to the surface of the ShoPed 606.

In one example, the angle or tilt at which the orifices in the edge hole region 607 is defined to tilt or angle away from the center of the ShoPed 106. In one embodiment, the angle is approximately 45° from horizontal. In other embodiments, the angle can vary between 20° from horizontal to about 80° from horizontal. In one embodiment, by providing the angled orifices in the edge hole region 607, additional distribution of process gases can be provided during backside deposition of the wafer 602. In one embodiment, the remainder orifices 606d of the hole pattern 606a are oriented substantially perpendicular to the surface of the ShoPed 106 and directed toward the underside of the wafer 602.

FIG. 7B illustrates that when the wafer 602 is held by the carrier ring 654, the wafer 602 edge will sit on an edge region closer to the carrier ring inner radius 654a of the carrier ring 654. The surface of the showerhead 636 facing the top surface of the wafer 602, when positioned using spacers 644, may be substantially close to prevent deposition during a mode where deposition is being carried out to the backside of the wafer 602.

By way of example, the distance between the top of the wafer 602 and the surface of the showerhead 636 is preferably between about 2 mm to about 0.5 mm, and in some embodiments about 1 mm to about 0.5 mm, depending on the wafer bow. That is, if the wafer is bowed substantially, the separation will be about 0.5 mm or larger. If the wafer is not yet bowed substantially, the separation can be less than about 0.5 mm. In one embodiment, it is preferable that the separation be minimized to prevent deposition on the top side of the substrate when the backside of the substrate is being deposited with a layer of material. In some embodiments, the showerhead 636 is configured to supply an inert gas flow over the top side of the wafer 602 during when the backside of the substrate is being deposited and deposition gases are being supplied by the ShoPed 606.

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems.

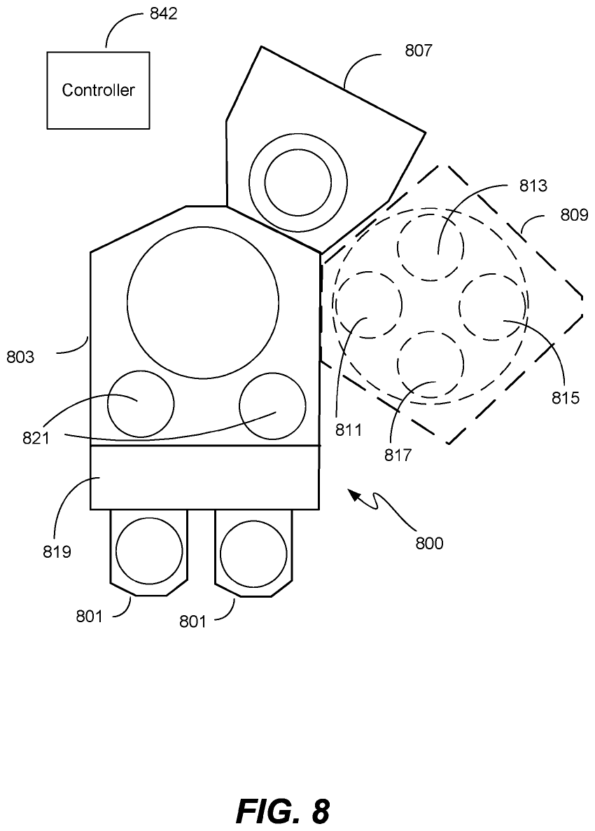

FIG. 8 is a schematic of a process system suitable for conducting deposition processes, such as frontside deposition processes, in accordance with embodiments. The system 800 includes a transfer module 803. The transfer module 803 provides a clean, pressurized environment to minimize risk of contamination of substrates being processed as they are moved between various reactor modules. Mounted on the transfer module 803 is a multi-station reactor 809 capable of performing ALD, treatment, and CVD according to various embodiments. Multi-station reactor 809 may include multiple stations 811, 813, 815, and 817 that may sequentially perform operations in accordance with disclosed embodiments. Stations may include a heated pedestal or substrate support, one or more gas inlets or showerhead or dispersion plate.

Mounted on the transfer module 803 may be one or more single or multi-station modules 807 capable of performing plasma or chemical (non-plasma) pre-cleans, other deposition operations, or etch operations. The module may also be used for various treatments to, for example, prepare a substrate for a deposition process. The system 800 also includes one or more wafer source modules 801, where wafers are stored before and after processing. An atmospheric robot (not shown) in the atmospheric transfer chamber 819 may first remove wafers from the wafer source modules 801 to loadlocks 821. A wafer transfer device (generally a robot arm unit) in the transfer module 803 moves the wafers from loadlocks 821 to and among the modules mounted on the transfer module 803.

In various embodiments, a system controller 842 is employed to control process conditions during deposition. The system controller 842 will typically include one or more memory devices and one or more processors. A processor may include a CPU or computer, analog and/or digital input/output connections, stepper motor controller boards, etc.

The system controller 842 may control all the activities of the deposition apparatus. The system controller 842 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the system controller 842 may be employed in some embodiments.

The depicted embodiment includes a user interface associated with the system controller 842. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 842. The signals for controlling the process are output on the analog and digital output connections of the system 800.

The system software may be designed or configured in different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a system controller 842 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 842, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

### System Controllers

Broadly speaking, a controller may be defined as electronics having various integrated circuits, logic, memory, and/or software that receive instructions, issue instructions, control operation, enable cleaning operations, enable endpoint measurements, and the like. Such controller may be used in or with any of the apparatus described herein. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

A system controller may be a part of or coupled to a computer that is integrated with, coupled to the system, otherwise networked to the system, or a combination thereof. For example, a system controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

A system controller may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Conclusion

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of reducing bow in a substrate, the method comprising:
receiving a substrate having a frontside and a backside, wherein the substrate has a first bow in an x-direction of the substrate and a second bow in a y-direction of the substrate;
performing one or more cycles of:
(a) forming a first backside layer on the backside of the substrate, wherein the first backside layer compensates the first bow more than it compensates the second bow or compensates the second bow more than it compensates the first bow, and wherein the first backside layer has a first type of internal stress and a first non-uniform thickness profile;
(b) forming a second backside layer on the backside of the substrate, wherein the second backside layer compensates either of the first bow or the second bow that was less compensated by the first backside layer, wherein the second backside layer has a second type of internal stress, which is opposite the first type of internal stress, and a second non-uniform thickness profile; and
wherein the first non-uniform thickness profile and the second non-uniform thickness profile complement each other, such that when the first backside layer and second backside layers are formed, they provide a complementary film stack having a substantially flat surface on the backside of the substrate.

2. The method of claim 1, wherein the substrate is a semiconductor wafer having partially fabricated integrated circuits on the front side.

3. The method of claim 1, wherein the substrate has a saddle-shaped bow.

4-5. (canceled)

6. The method of claim 1, wherein the first non-uniform thickness profile is a curved bar that is thicker toward a center of the substrate than edges of the substrate.

7. The method of claim 6, wherein the curved bar has a longitudinal axis that is substantially parallel to the y-direction.

8. The method of claim 6, wherein the curved bar has a generally parabolic shape that varies in thickness in a z-direction perpendicular to the x-and y-directions, away from the backside of the substrate as a function of the x-direction.

9. The method of claim 1, wherein the second non-uniform thickness profile is a curved channel that is thicker toward edges of the substrate than a center of the substrate.

10. The method of claim 9, wherein the curved channel has a parabolic shape that varies in thickness in a z-direction, away from the backside of the substrate as a function of the x-direction.

11-12. (canceled)

13. The method of claim 1, further comprising forming a third backside layer on the backside of the substrate, wherein the third backside layer has a uniform shape and either the first or the second type of internal stress.

14. The method of claim 13, wherein the type of internal stress and a magnitude of the internal stress of the third backside layer is based upon the bow of the substrate after forming the first backside layer and the second backside layer.

15-16. (canceled)

17. The method of claim 1, wherein the one or more cycles are two or more cycles.

18. The method of claim 1, wherein a total thickness of layers deposited during the one or more cycles is at least about 2 μm.

19. The method of claim 1, wherein the first backside layer and the second backside layer together have a first thickness, and each cycle of (a) and (b) deposit complementary profile layers having the first thickness.

20. The method of claim 19, wherein the first thickness is less than about 1 μm.

21. The method of claim 1, wherein first backside layer and the second backside layer exhibit a change in wafer bow compensation after annealing less than about 20%.

22. The method of claim 1, further comprising, after performing the one or more cycles, forming a third backside layer on the backside of the substrate, wherein the third backside layer increases a flatness of the backside of the substrate.

23. (canceled)

24. A substrate comprising:
one or more frontside layers on a frontside of the substrate, wherein the substrate has a first bow in an x-direction of the substrate and a second bow in a y-direction of the substrate;
a first backside layer on a backside of the substrate, wherein the first backside layer compensates the first bow more than it compensates the second bow or compensates the second bow more than it compensates the first bow, and wherein the first backside layer has a first type of internal stress and a first non-uniform thickness profile;
a second backside layer on the backside of the substrate, wherein the second backside layer compensates either of the first bow or the second bow that was less compensated by the first backside layer, wherein the second backside layer has a second type of internal stress, which is opposite the first type of internal stress, and a second non-uniform thickness profile; and
wherein the first non-uniform thickness profile and the second non-uniform thickness profile complement each other, such that when the first backside layer and second backside layers are formed, they provide a complementary film stack having a substantially flat surface on the backside of the substrate.

25. (canceled)

26. The substrate of claim 24, wherein the first non-uniform thickness profile is a curved bar that is thicker toward a center of the substrate than edges of the substrate.

27-34. (canceled)

35. The substrate of claim 24, further comprising additional complementary film stacks.

36-40. (canceled)

41. An apparatus for semiconductor processing, the apparatus comprising:
a process chamber; and
a controller comprising memory and processors configured for:
receiving a substrate having a frontside and a backside, wherein the substrate has a first bow in an x-direction of the substrate and a second bow in a y-direction of the substrate;
performing one or more cycles of:
(a) forming a first backside layer on the backside of the substrate, wherein the first backside layer compensates the first bow more than it compensates the second bow or compensates the second bow more than it compensates the first bow, and wherein the first backside layer has a first type of internal stress and a first non-uniform thickness profile;
(b) forming a second backside layer on the backside of the substrate, wherein the second backside layer compensates either of the first bow or the second bow that was less compensated by the first backside layer, wherein the second backside layer has a second type of internal stress, which is opposite the first type of internal stress, and a second non-uniform thickness profile; and
wherein the first non-uniform thickness profile and the second non-uniform thickness profile complement each other, such that when the first backside layer and second backside layers are formed, they provide a complementary film stack having a substantially flat surface on the backside of the substrate.
